(19) United States
(12) Patent Application Publication
(10) Pub. No.: US 2018/0083588 A1
(43) Pub. Date: Mar. 22, 2018

(54) ELECTRODE WRAP-AROUND CAPACITORS FOR RADIO FREQUENCY (RF) APPLICATIONS

(71) Applicant: QUALCOMM Incorporated, San Diego, CA (US)

(72) Inventors: Changhan Hobie YUN, San Diego, CA (US); Shiqun GU, San Diego, CA (US); Je-Hsiung Jeffrey LAN, San Diego, CA (US); Jonghae KIM, San Diego, CA (US); Niranjan Sunil MUDAKATTE, San Diego, CA (US); David Francis BERDY, San Diego, CA (US); Mario Francisco VELEZ, San Diego, CA (US); Chengjie ZUO, San Diego, CA (US)

(21) Appl. No.: 15/350,969

(22) Filed: Nov. 14, 2016

Related U.S. Application Data
(60) Provisional application No. 62/396,754, filed on Sep. 19, 2016.

(51) Int. Cl. H03H 1/00; H01G 4/12; H01G 4/005; H01G 4/40; H03H 7/46

(52) U.S. Cl. CPC H03H 1/00; H01G 4/1209; H01G 4/005; H03H 2001/0014; H03H 7/46; H03H 2001/0021; H01G 4/40

(57) ABSTRACT

A capacitor may include a first capacitor plate having a first length. The capacitor may also include an inorganic capacitor dielectric layer on sidewalls and a surface of the first capacitor plate and a second capacitor plate on the inorganic capacitor dielectric layer. The second capacitor plate may have a second length less than the first length of the first capacitor plate. The capacitor may also include a conductive contact landing directly on the first capacitor plate. The conductive contact may land directly on the first capacitor plate by extending through the inorganic capacitor dielectric layer and an organic interlayer dielectric supported by the inorganic capacitor dielectric layer.

### CROSS-REFERENCE TO RELATED APPLICATION

The present application claims the benefit of U.S. Provisional Patent Application No. 62/396,754, filed on Sep. 19, 2016, and titled “ELECTRODE WRAP-AROUND CAPACITORS FOR RADIO FREQUENCY (RF) APPLICATIONS,” the disclosure of which is expressly incorporated by reference herein in its entirety.

### BACKGROUND

### Field

Aspects of the present disclosure relate to semiconductor devices, and more particularly to electrode wrap-around capacitors for radio frequency (RF) applications having improved passive on glass (POG) multiplexer performance.

### Background

One goal driving the wireless communication industry is providing consumers with increased bandwidth. The use of carrier aggregation in current generation communications provides one possible solution for achieving this goal. Carrier aggregation enables a wireless carrier, having licenses to two frequency bands (e.g., 700 MHz and 2 GHz) in a particular geographic area, to maximize bandwidth by simultaneously using both frequencies for a single communication stream. While an increased amount of data is provided to the end user, carrier aggregation implementation is complicated by noise created at the harmonic frequencies due to the frequencies used for data transmission. For example, 700 MHz transmissions may create harmonics at 2.1 GHz, which interfere with data broadcast at 2 GHz frequencies.

For wireless communication, passive devices are used to process signals. In carrier aggregation systems, signals are communicated with both high band and low band frequencies. In a chipset, a passive device (e.g., a diplexer) is usually inserted between an antenna and a tuner (or a radio frequency (RF) switch) to ensure high performance. Usually, a diplexer design includes inductors and capacitors. Diplexers can attain high performance by using inductors and capacitors that have a high quality (Q)-factor. High performance diplexers can also be attained by reducing the electromagnetic coupling between components, which may be achieved through an arrangement of the geometry and direction of the components.

Mobile RF chip designs (e.g., mobile RF transceivers), including high performance multiplexers have migrated to a deep sub-micron process node due to cost and power consumption considerations. The design of such mobile RF transceivers becomes complex at this deep sub-micron process node. The design complexity of these mobile RF transceivers is further complicated by added circuit functions to support communication enhancements, such as carrier aggregation. Further design challenges for mobile RF transceivers include analog/RF performance considerations, including mismatch, noise and other performance considerations. The design of these mobile RF transceivers includes the use of additional passive devices, for example, to suppress resonance, and/or to perform filtering, bypassing, and coupling.

Passive on glass devices involve high-performance inductor and capacitor components that have a variety of advantages over other technologies, such as surface mount technology or multi-layer ceramic chips that are commonly used in the fabrication of mobile radio frequency (RF) chips. The design complexity of mobile RF transceivers is complicated by the migration to a deep sub-micron process node due to cost and power consumption considerations. Spacing considerations also affect mobile RF transceiver design at deep sub-micron process nodes, such as capacitor plate shorting, which may cause a performance degradation for RF multiplexers.

### SUMMARY

A capacitor may include a first capacitor plate having a first length. The capacitor may also include an inorganic capacitor dielectric layer on sidewalls and a surface of the first capacitor plate and a second capacitor plate on the inorganic capacitor dielectric layer. The second capacitor plate may have a second length less than the first length of the first capacitor plate. The capacitor may also include a conductive contact landing directly on the first capacitor plate. The conductive contact may land directly on the first capacitor plate by extending through the inorganic capacitor dielectric layer and an organic interlayer dielectric supported by the inorganic capacitor dielectric layer.

A capacitor may include a first capacitor plate having a first length. The capacitor may also include a second capacitor plate supported by the first capacitor plate. The second capacitor plate may have a second length less than the first length. The capacitor may further include an inorganic capacitor dielectric layer between the first capacitor plate and the second capacitor plate. The inorganic capacitor dielectric layer may be arranged on sidewalls and on surfaces of the second capacitor plate. The capacitor may also include a first conductive contact landing directly on the second capacitor plate. The first conductive contact may extend through the inorganic capacitor dielectric layer and an organic interlayer dielectric supported by the inorganic capacitor dielectric layer.

A method of constructing a capacitor may include depositing a first conductive interconnect layer to form a first capacitor plate having a first length. The method may also include depositing an inorganic capacitor dielectric layer on at least the first capacitor plate. The method may further include depositing a second conductive interconnect layer on the inorganic capacitor dielectric layer to form a second capacitor plate. The second capacitor plate may have a second length less than the first length. The method may also include fabricating a conductive contact landing directly on at least one of the first capacitor plate or the second capacitor plate. The conductive contact may land directly on the first capacitor plate and/or the second capacitor plate by extending through the inorganic capacitor dielectric layer and an organic interlayer dielectric supported by the inorganic capacitor dielectric layer.

A radio frequency (RF) front end module may include a filter. The filter may be composed of a capacitor having first capacitor plate having a first length, an inorganic capacitor dielectric layer on at least the first capacitor plate, and a second capacitor plate on the inorganic capacitor dielectric layer. The second capacitor plate may have a second length less than the first length of the first capacitor plate. The filter may include a conductive contact landing directly on at least one of the first capacitor plate or the second capacitor plate. The conductive contact may land directly on the first capacitor plate and/or the second capacitor plate by extending through the inorganic capacitor dielectric layer and an organic interlayer dielectric supported by the inorganic capacitor dielectric layer. The RF front end module may also include a diplexer coupled to the filter. The RF front end module may also include an antenna coupled to an output of the diplexer.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1A is a schematic diagram of a radio frequency (RF) front end (RFFE) module.

FIG. 1B is a schematic diagram of a radio frequency (RF) front end (RFFE) module employing diplexers for a chipset to provide carrier aggregation.

FIG. 2A is a diagram of a diplexer design.

FIG. 2B is a diagram of a radio frequency (RF) front end (RFFE) module.

FIG. 3 shows a cross-section view of an electrode wrap-around capacitor structure according to aspects of the present disclosure.

FIGS. 4A to 4C show cross-section views of electrode wrap-around capacitor structures according to aspects of the present disclosure.

FIGS. 5A-5D show cross-section views of series coupled, electrode wrap-around capacitor structures according to aspects of the present disclosure.

FIG. 6 shows a cross-section view of a series coupled, electrode wrap-around capacitor structure according to aspects of the present disclosure.

FIG. 7 shows cross-section views during fabrication of the electrode wrap-around capacitor structure of FIG. 3 according to aspects of the present disclosure.

FIG. 8 illustrates a method of constructing a wrap-around electrode capacitor structure in accordance with an aspect of the present disclosure.

FIG. 9 is a block diagram showing an exemplary wireless communication system in which an aspect of the present disclosure may be advantageously employed.

FIG. 10 is a block diagram illustrating a design workstation used for circuit, layout, and logic design of the electrode wrap-around capacitors according to one aspect of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Mobile radio frequency (RF) chip designs (e.g., mobile RF transceivers), including high performance multiplexers have migrated to a deep sub-micron process node due to cost and power consumption considerations. The design of such mobile RF transceivers becomes complex at this deep sub-micron process node. The design complexity of these mobile RF transceivers is further complicated by added circuit functions to support communication enhancements, such as carrier aggregation. Further design challenges for mobile RF transceivers include analog/RF performance considerations, including mismatch, noise and other performance considerations. The design of these mobile RF transceivers includes the use of additional passive devices, for example, to suppress resonance, and/or to perform filtering, bypassing and coupling.

Successful fabrication of modern semiconductor chip products involves interplay between the materials and the processes employed. In particular, the formation of passive devices during semiconductor fabrication in back-end-of-line (BEOL) processes is an increasingly challenging part of the process flow. This is particularly true in terms of maintaining a small feature size. The same challenge of maintaining a small feature size also applies to passive on glass (POG) technology, where high performance components such as inductors and capacitors are built upon a highly insulative substrate that may also have a very low loss to support mobile RF transceiver design.

Passive on glass devices involve high-performance inductor and capacitor components that have a variety of advantages over other technologies, such as surface mount technology or multi-layer ceramic chips that are commonly used in the fabrication of mobile RF chips. The design complexity of mobile RF transceivers is complicated by the migration to a deep sub-micron process node due to cost and power consumption considerations. Spacing considerations also affect mobile RF transceiver design at deep sub-micron process nodes, such as capacitor plate shorting, which may cause a performance degradation for RF multiplexers.

Capacitors are passive elements used in integrated circuits for storing an electrical charge. Capacitors are often composed of plates or structures that are conductive with an insulating material between them. The amount of storage, or capacitance, for a given capacitor is contingent upon the materials used to make the plates and the insulator, the area of the plates, and the spacing between the plates. The insulating material is often a dielectric material. Metal-insulator-metal (MIM) capacitors are one example of a parallel plate capacitor, in which the insulator is a dielectric material, and the plates are made of a conductive material (e.g., metal).

Parallel plate capacitors are frequently employed in semiconductor dies to provide capacitance to circuitry on the semiconductor dies. Parallel plate capacitors are increasingly used to improve performance of devices that operate at higher frequencies. For example, MIM capacitors are often used in high frequency (e.g., radio frequency (RF)) telecommunications applications, such as cell phones, wireless devices, and other telecommunications products. Often, MIM capacitors provide various functions in an integrated circuit such as decoupling with a power supply, analog-to-digital conversions and filtering, and termination of transmission lines. Decoupling applications generally have relatively loose leakage current specifications, whereas analog application typically involves closer capacitor matching and relatively good voltage linearity. Moreover, in many telecommunications applications, particularly in handheld applications, low loss and relatively low temperature linearity are desired.

Unfortunately, parallel plate capacitors (e.g., MIM capacitors) may suffer from unintended sidewall plate connections. These unintended sidewall plate connections short the capacitor plates, which reduces the performance of an RF device (e.g., a multiplexer/diplexer) that includes these shorted parallel plate capacitors. An unintended sidewall connection of a parallel plate capacitor may be due to re-deposition of a conductive material (e.g., aluminum (Al)) of one of the capacitor plates (e.g., a bottom capacitor plate) during capacitor dielectric etching. An unintended sidewall connection of the parallel plate capacitors may also be due to growth of a conductive whisker or nodule of a conductive material (e.g., a copper (Cu) whisker) of one of the capacitor plates (e.g., a bottom capacitor plate) during thermally activated diffusion.

For an increasing number of applications RF linearity is a significant performance consideration. One such application example is a multiplexer or diplexer of a radio frequency (RF) front end (RFFE) device that accommodates a wide range of radio frequencies (e.g., from a base band of 700 MHz all the way to 20 GHz or higher) to support carrier aggregation. The multiplexer/diplexer is generally designed with many parallel plate capacitors. Unfortunately, RF linearity is drastically degraded when the parallel plate capacitors suffer from unintended sidewall plate connections that short the capacitor plates.

Aspects of the present disclosure propose electrode wrap-around capacitors for radio frequency (RF) applications with improved passive on glass (POG) multiplexer performance. According to one aspect of the present disclosure, an electrode wrap-around capacitor includes a first capacitor plate having a first length. The capacitor also includes an inorganic capacitor dielectric layer on at least the first capacitor plate. The capacitor further includes a second capacitor plate on the inorganic capacitor dielectric layer. The second capacitor plate may have a second length less than the first length of the first capacitor plate. The inorganic capacitor dielectric layer may be extended to prevent shorting between the second capacitor plate (e.g., a top electrode of metal two (M2)) and the first capacitor plate (e.g., a bottom electrode of metal one (M1)).

The capacitor also includes a conductive contact landing directly on the first capacitor plate or the second capacitor plate. For example, depending on the arrangement of the inorganic capacitor dielectric, the conductive contact extends through the inorganic capacitor dielectric layer and an organic interlayer dielectric supported by the inorganic capacitor dielectric layer to contact either the first capacitor plate or the second capacitor plate. One advantage of this approach is that the fabrication process is relatively simple because the electrode wrap-around capacitor is fabricated without adding a mask layer. In addition, the electrode wrap-around capacitor provides improved RF linearity.

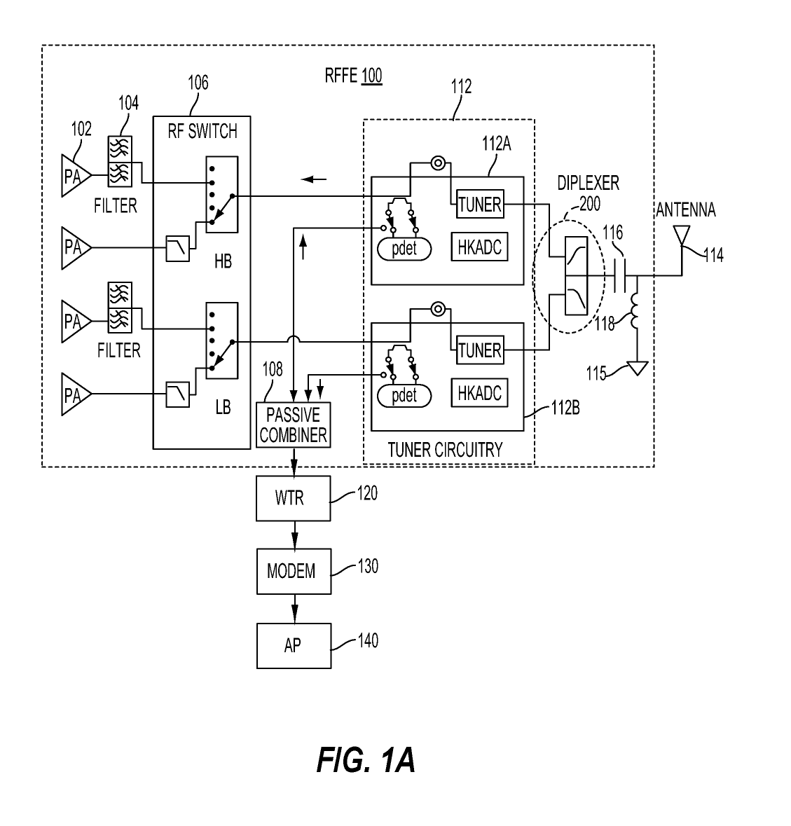

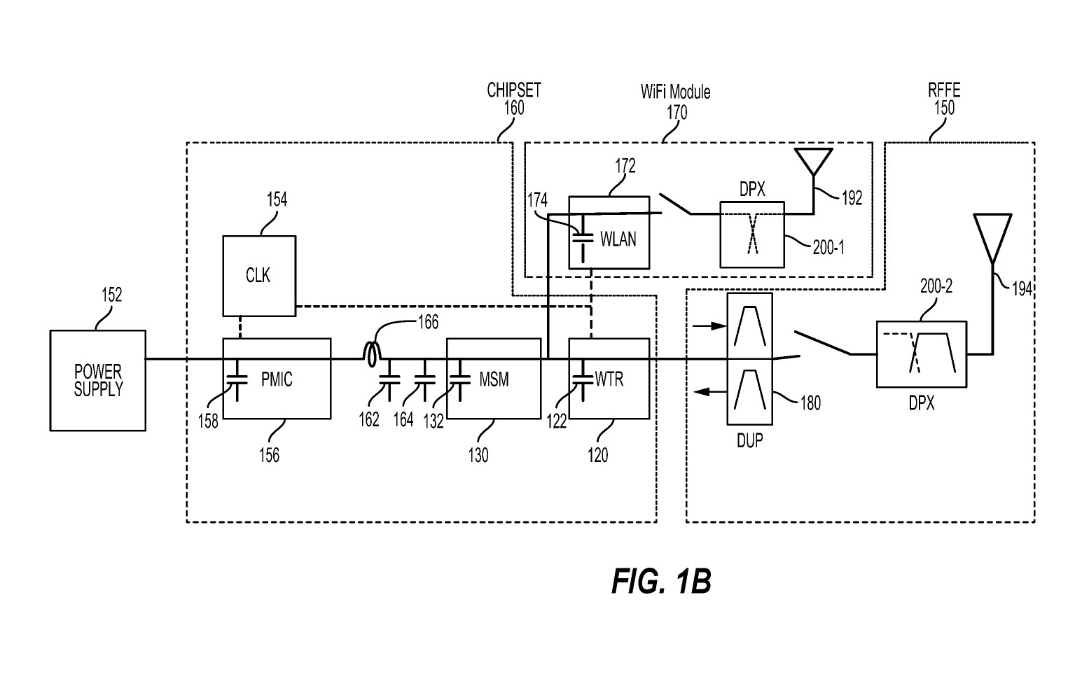

FIG. 1A is a schematic diagram of a radio frequency (RF) front end (RFFE) module 100 employing a diplexer 200. The RF front end module 100 includes power amplifiers 102, duplexer/filters 104, and a radio frequency (RF) switch module 106. The power amplifiers 102 amplify signal(s) to a certain power level for transmission. The duplexer/filters 104 filter the input/output signals according to a variety of different parameters, including frequency, insertion loss, rejection or other like parameters. In addition, the RF switch module 106 may select certain portions of the input signals to pass on to the rest of the RF front end module 100.

The RF front end module 100 also includes tuner circuitry 112 (e.g., first tuner circuitry 112A and second tuner circuitry 112B), the diplexer 200, a capacitor 116, an inductor 118, a ground terminal 115 and an antenna 114. The tuner circuitry 112 (e.g., the first tuner circuitry 112A and the second tuner circuitry 112B) includes components such as a tuner, a portable data entry terminal (PDET), and a house keeping analog to digital converter (HKADC). The tuner circuitry 112 may perform impedance tuning (e.g., a voltage standing wave ratio (VSWR) optimization) for the antenna 114. The RF front end module 100 also includes a passive combiner 108 coupled to a wireless transceiver (WTR) 120. The passive combiner 108 combines the detected power from the first tuner circuitry 112A and the second tuner circuitry 112B. The wireless transceiver 120 processes the information from the passive combiner 108 and provides this information to a modem 130 (e.g., a mobile station modem (MSM)). The modem 130 provides a digital signal to an application processor (AP) 140.

As shown in FIG. 1A, the diplexer 200 is between the tuner component of the tuner circuitry 112 and the capacitor 116, the inductor 118, and the antenna 114. The diplexer 200 may be placed between the antenna 114 and the tuner circuitry 112 to provide high system performance from the RF front end module 100 to a chipset including the wireless transceiver 120, the modem 130 and the application processor 140. The diplexer 200 also performs frequency domain multiplexing on both high band frequencies and low band frequencies. After the diplexer 200 performs its frequency multiplexing functions on the input signals, the output of the diplexer 200 is fed to an optional LC (inductor/capacitor) network including the capacitor 116 and the inductor 118. The LC network may provide extra impedance matching components for the antenna 114, when desired. Then, a signal with the particular frequency is transmitted or received by the antenna 114. Although a single capacitor and inductor are shown, multiple components are also contemplated.

FIG. 1B is a schematic diagram of a wireless local area network (WLAN) (e.g., WiFi) module 170 including a first diplexer 200-1 and an RF front end (RFFE) module 150 including a second diplexer 200-2 for a chipset 160 to provide carrier aggregation. The WiFi module 170 includes the first diplexer 200-1 communicably coupling an antenna 192 to a wireless local area network module (e.g., WLAN module 172). The RF front end module 150 includes the second diplexer 200-2 communicably coupling an antenna 194 to the wireless transceiver (WTR) 120 through a duplexer 180. The wireless transceiver 120 and the WLAN module 172 of the WiFi module 170 are coupled to a modem (MSM, e.g., baseband modem) 130 that is powered by a power supply 152 through a power management integrated circuit (PMIC) 156. The chipset 160 also includes capacitors 162 and 164, as well as an inductor(s) 166 to provide signal integrity. The PMIC 156, the modem 130, the wireless transceiver 120, and the WLAN module 172 each include capacitors (e.g., 158, 132, 122, and 174) and operate according to a clock 154. The geometry and arrangement of the various inductor and capacitor components in the chipset 160 may reduce the electromagnetic coupling between the components.

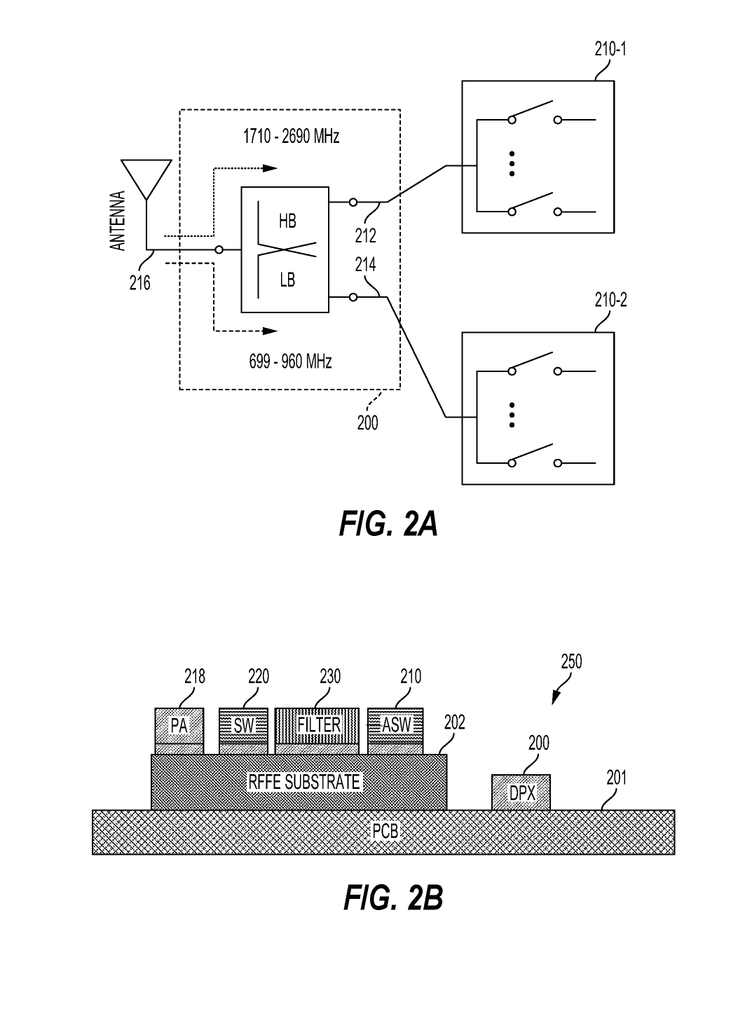

FIG. 2A is a diagram of a diplexer 200. The diplexer 200 includes a high band (HB) input port 212, a low band (LB) input port 214, and an antenna 216. A high band path of the diplexer 200 includes a high band antenna switch 210-1. A low band path of the diplexer 200 includes a low band antenna switch 210-2. A wireless device including an RF front end module may use the antenna switches 210 and the diplexer 200 to enable a wide range band for an RF input and an RF output of the wireless device. In addition, the antenna 216 may be a multiple input, multiple output (MIMO) antenna. Multiple input, multiple output antennas will be widely used for the RF front end of wireless devices to support features such as carrier aggregation.

FIG. 2B is a diagram of an RF front end module 250. The RF front end module 250 includes the antenna switch (ASW) 210 and diplexer 200 (or triplexer) to enable the wide range band noted in FIG. 2A. In addition, the RF front end module 250 includes filters 230, an RF switch 220 and power amplifiers 218 supported by a substrate 202. The filters 230 may include various LC filters, having inductors (L) and capacitors (C) arranged along the substrate 202 for forming a diplexer, a triplexer, low pass filters, balun filters, and/or notch filters to prevent high order harmonics in the RF front end module 250.

In this configuration, the diplexer 200 is implemented as a surface mount device (SMD) on a system board 201 (e.g., printed circuit board (PCB) or package substrate). By contrast, the antenna switch 210 is implemented on the substrate 202 supported by the system board 201 of the RF front end module 250. In addition, the various LC filters of the filters 230 are also implemented as surface mount devices on the substrate 202 of the RF front end module 250. Although shown as filters 230, the LC filters including a low pass filter(s) and/or a notch filter(s) are arranged throughout the substrate using pick and place technology to prevent high order harmonics in the RF front end module 250.

The RF front end module 250 generally includes many parallel plate capacitators. Unfortunately, parallel plate capacitors suffer from unintended sidewall plate connections. These unintended sidewall plate connections short the capacitor plates, which reduces the performance of an RF device (e.g., a multiplexer/diplexer) that includes these shorted parallel plate capacitors. An unintended sidewall connection of a parallel plate capacitor may be due to re-deposition of a conductive material (e.g., aluminum (Al)) of one of the capacitor plates (e.g., a bottom capacitor plate) during capacitor dielectric etching. An unintended sidewall connection of the parallel plate capacitors may also be due to growth of a conductive whisker or nodule of a conductive material (e.g., a copper (Cu) whisker) of one of the capacitor plates (e.g., a bottom capacitor plate) during thermally-activated diffusion.

According to aspects of the present disclosure, a multiplexer or the diplexer 200 of the RF front end module 250 includes electrode wrap-around capacitors for accommodating a wide range of radio frequencies (e.g., from a base band of 700 MHz all the way to 20 GHz or higher) to support carrier aggregation. The multiplexer/diplexer is generally designed with many parallel plate capacitors. Unfortunately, RF linearity is degraded when the parallel plate capacitors suffer from unintended sidewall plate connections that short the capacitor plates.

Various aspects of the present disclosure provide electrode wrap-around capacitors for radio frequency (RF) applications with improved passive on glass (POG) multiplexer performance. According to one aspect of the present disclosure, an electrode wrap-around capacitor includes a first capacitor plate and an inorganic capacitor dielectric layer on at least the first capacitor plate. The capacitor also includes a second capacitor plate, which may have a second length less than a first length of the first capacitor plate.

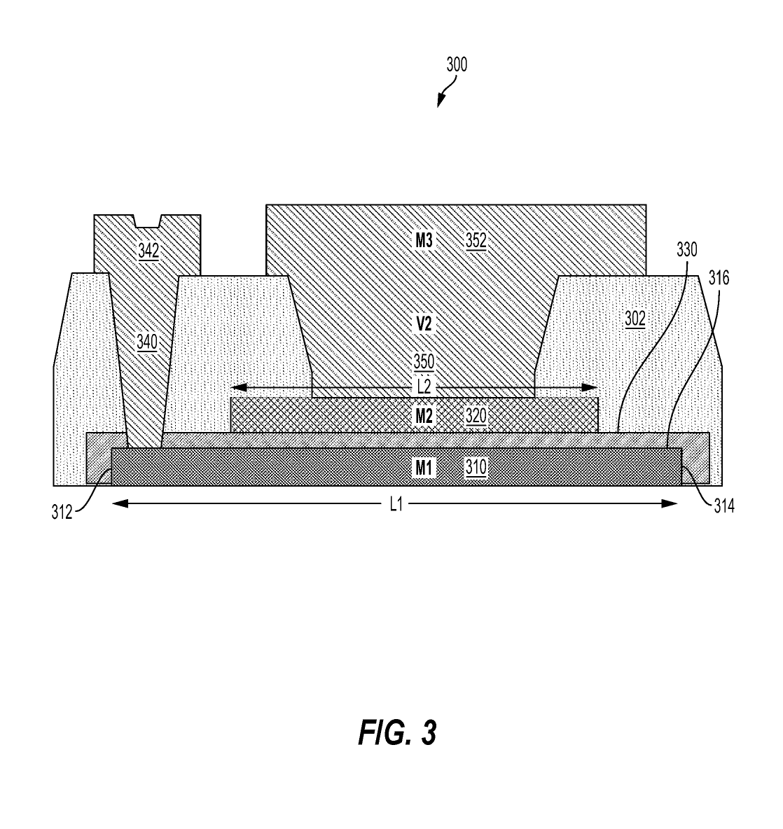

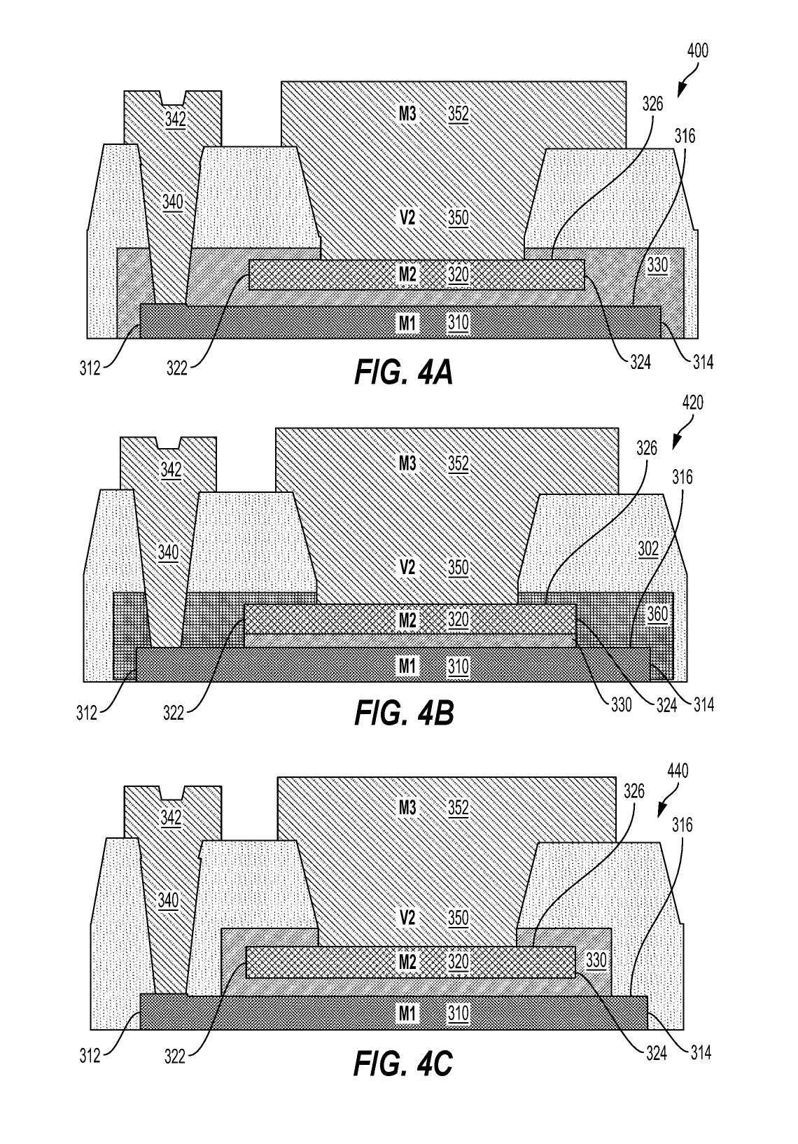

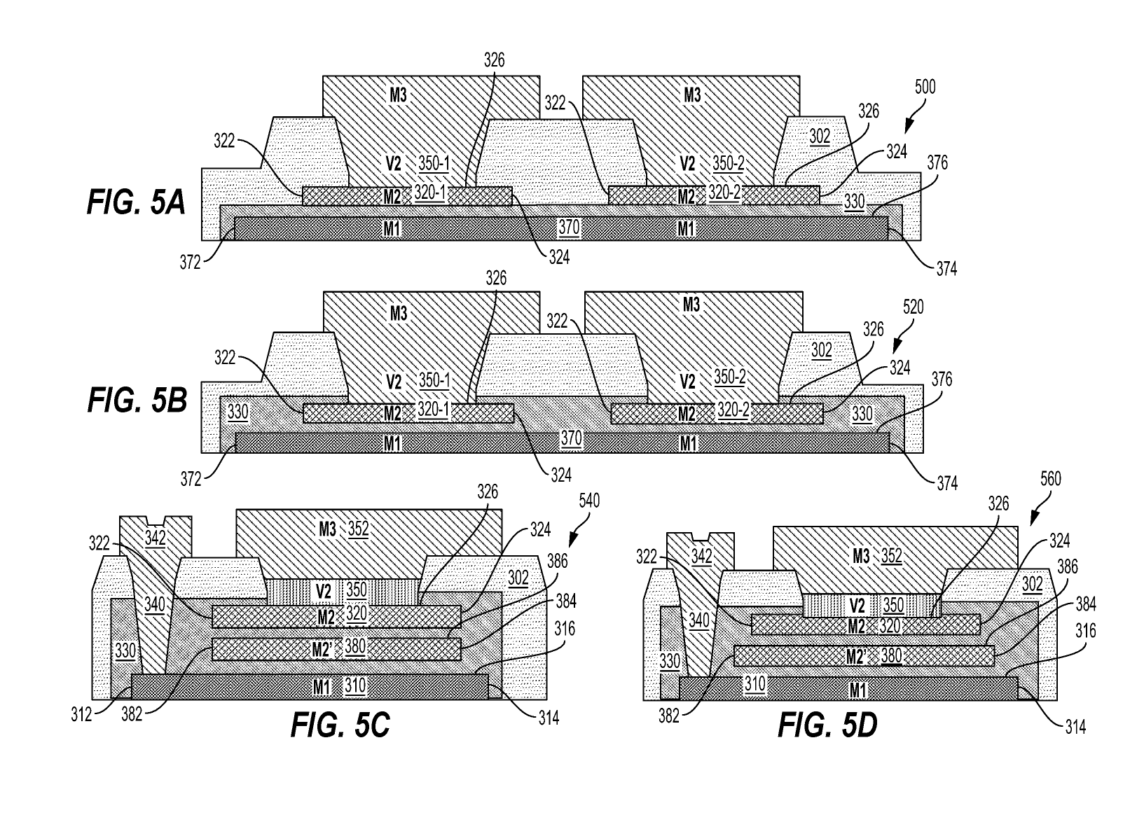

According to aspects of the present disclosure, the inorganic capacitor dielectric layer may be extended to prevent shorting between the second capacitor plate (e.g., a top electrode of metal two (M2)) and the first capacitor plate (e.g., a bottom electrode of metal one (M1)), for example, as shown in FIG. 3. In other configurations, the inorganic capacitor dielectric layer may wrap around the first capacitor plate or the second capacitor plate, for example, as shown in FIGS. 4A and 4C. These variations may enable serial capacitor arrangements including electrode wrap-around, as shown in FIGS. 5A-D and 6.

FIG. 3 shows a cross-section view of an electrode wrap-around capacitor structure 300, according to aspects of the present disclosure. In this configuration, the electrode wrap-around capacitor structure 300 includes a first capacitor plate 310 having a first length (L1). The electrode wrap-around capacitor also includes an inorganic capacitor dielectric layer 330 on at least the first capacitor plate 310. The inorganic capacitor dielectric layer 330 may be silicon nitride (SiN), aluminum oxide (AlO), tantalum oxide, or other like inorganic material. The electrode wrap-around capacitor structure 300 further includes a second capacitor plate 320 on the inorganic capacitor dielectric layer 330. The second capacitor plate has a second length (L2) less than the first length (L1) of the first capacitor plate 310. The extended length of the first capacitor plate 310 enables an extension of the inorganic capacitor dielectric layer 330 for preventing shorting between the second capacitor plate 320 (e.g., a top electrode of metal two (M2)) and the first capacitor plate 310 (e.g., a bottom electrode of metal one (M1)).

The electrode wrap-around capacitor structure 300 also includes a first conductive contact 340 (e.g., a via) landing directly the first capacitor plate 310. For example, depending on the arrangement of the inorganic capacitor dielectric layer 330, the first conductive contact 340 extends through the inorganic capacitor dielectric layer 330 and an organic interlayer dielectric 302 to directly contact the first capacitor plate 310. The organic interlayer dielectric 302 may be polyimide (Pl), benzocyclobutene (BCB), or other like organic material. The extension of the inorganic capacitor dielectric layer 330 and the first capacitor plate 310 enables support for the organic interlayer dielectric 302, which does not contact the first capacitor plate 310. In this arrangement, the inorganic capacitor dielectric layer 330 wraps around the first capacitor plate 310 because the inorganic capacitor dielectric layer 330 is on a surface 316 as well as a first sidewall 312 and a second sidewall 314 of the first capacitor plate 310.

As further illustrated in FIG. 3, the first conductive contact 340 includes a first portion 342 of a third interconnect layer (e.g., metal 3 (M3)) on a surface of the organic interlayer dielectric 302. A second conductive contact 350 (e.g., a via two (V2)) extends through the organic interlayer dielectric 302 and lands directly on the second capacitor plate 320. The second conductive contact 350 also includes a second portion 352 of the third interconnect layer M3 on the surface of the organic interlayer dielectric 302. The third conductive interconnect layer, the first conductive contact 340, and the second conductive contact 350 may be composed of copper (Cu), or other like conductive material.

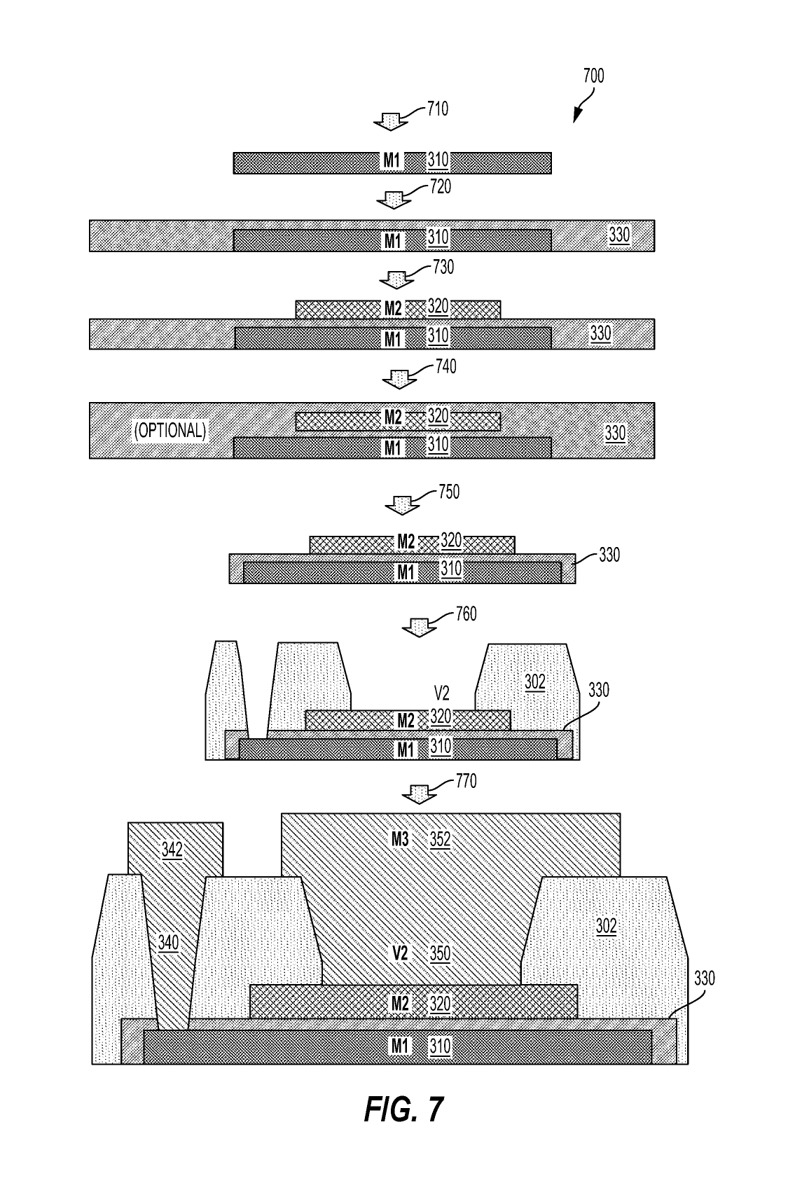

In this configuration, the first capacitor plate 310 may be fabricated using a first back-end-of-line (BEOL) interconnect layer M1. In addition, the second capacitor plate 320 may be fabricated using a second BEOL interconnect layer M2, with the first capacitor plate 310 and the second capacitor plate 320 composed of aluminum (Al), copper (Cu), or other like conductive material. It should be recognized that the lengths and widths of the electrode wrap-around capacitor structure 300 are not drawn to scale and are for the purpose of illustration. Fabrication of the electrode wrap-around capacitor structure 300 will be described later with respect to FIG. 7.

FIGS. 4A to 4C show cross-section views of electrode wrap-around capacitor structures according to aspects of the present disclosure.

FIG. 4A is a cross-sectional view of an electrode wrap-around capacitor structure 400 according to aspects of the present disclosure. This aspect of the present disclosure solves the problem of unintended sidewall connections of parallel plate capacitors by wrapping an inorganic capacitor dielectric layer 330 around the first capacitor plate 310 and the second capacitor plate 320. As will be recognized, a configuration of the electrode wrap-around capacitor structure 400 is similar to the configuration of the electrode wrap-around capacitor structure 300 of FIG. 3. In the configuration shown in FIG. 4A, however, the inorganic capacitor dielectric layer 330 is also on a first sidewall 322, a surface 326, and a second sidewall 324 of the second capacitor plate 320. This arrangement of the inorganic capacitor dielectric layer 330 further prevents shorting between the first capacitor plate 310 and the second capacitor plate 320.

FIG. 4B is a cross-sectional view of an electrode wrap-around capacitor structure 420 according to aspects of the present disclosure. As will be recognized, a configuration of the electrode wrap-around capacitor structure 420 is similar to the configuration of the electrode wrap-around capacitor structure 400 of FIG. 4A. In the configuration shown in FIG. 4B, however, the inorganic capacitor dielectric layer 330 is between the first capacitor plate 310 and the second capacitor plate 320. As a result, a length of the inorganic capacitor dielectric layer 330 equals the length L2 (FIG. 3) of the second capacitor plate 320. In addition, the inorganic capacitor dielectric layer 330 may include a capacitor portion, between the first capacitor plate 310 and the second capacitor plate 320, and a protection portion, shown as a diffusion barrier layer 360. The protection portion and the capacitor portion of the inorganic capacitor dielectric layer may be composed of different materials.

In this arrangement, the diffusion barrier layer 360 (protection portion) wraps around the first capacitor plate 310 because the diffusion barrier layer 360 is on a surface 316 as well as a first sidewall 312 and a second sidewall 314 of the first capacitor plate 310. The diffusion barrier layer 360 also wraps around the second capacitor plate 320 because the diffusion barrier layer 360 is on a surface 326 as well as a first sidewall 322 and a second sidewall 324 of the second capacitor plate 320. In addition, the first conductive contact 340 extends through the organic interlayer dielectric 302 and the diffusion barrier layer 360 to land directly on the first capacitor plate 310. Similarly, the second conductive contact 350 extends through the organic interlayer dielectric 302 and the diffusion barrier layer 360 to land directly on the second capacitor plate 320. The diffusion barrier layer 360 may be composed of titanium nitride (TiN), tantalum nitride (TaN), silicon nitride (SiN), or other like protection dielectric materials. This arrangement of the diffusion barrier layer 360 also prevents shorting between the first capacitor plate 310 and the second capacitor plate 320.

FIG. 4C is a cross-sectional view of an electrode wrap-around capacitor structure 440 according to aspects of the present disclosure. This aspect of the present disclosure solves the problem of unintended sidewall connections of parallel plate capacitors by wrapping an inorganic capacitor dielectric layer 330 around the second capacitor plate 320. As will be recognized, a configuration of the electrode wrap-around capacitor structure 440 is similar to the configuration of the electrode wrap-around capacitor structure 400 of FIG. 4A. In the configuration shown in FIG. 4C, however, the inorganic capacitor dielectric layer 330 only wraps around the second capacitor plate 320 by being on the first sidewall 322, the surface 326, and the second sidewall 324 of the second capacitor plate 320. This arrangement of the inorganic capacitor dielectric layer 330 also prevents shorting between the first capacitor plate 310 and the second capacitor plate 320.

FIGS. 5A-5D show cross-section views of series coupled, electrode wrap-around capacitor structures according to aspects of the present disclosure.

FIG. 5A is a cross-sectional view of a series coupled, electrode wrap-around capacitor structure 500 according to an aspect of the present disclosure. This aspect of the present disclosure solves the problem of unintended sidewall connections for series coupled, parallel plate capacitors by wrapping an inorganic capacitor dielectric layer 330 around a shared first capacitor plate 370. As will be recognized, a configuration of the electrode wrap-around capacitor structure 500 is similar to the configuration of the electrode wrap-around capacitor structure 300 of FIG. 3. In the configuration shown in FIG. 5A, however, the shared first capacitor plate 370 is shared by a first, second capacitor plate 320-1 and a second, second capacitor plate 320-2. In addition, the inorganic capacitor dielectric layer 330 is on a first sidewall 372, a surface 376, and a second sidewall 374 of the shared first capacitor plate 370. In this arrangement, a first, second conductive contact 350-1 lands directly on the first, second capacitor plate 320-1, and a second, second conductive contact 350-2 lands directly on the second, second capacitor plate 320-2 through the organic interlayer dielectric 302.

FIG. 5B is a cross-sectional view of a series coupled, electrode wrap-around capacitor structure 520 according to an aspect of the present disclosure. As will be recognized, a configuration of the electrode wrap-around capacitor structure 520 is similar to the configuration of the series coupled, electrode wrap-around capacitor structure 500 of FIG. 5A. In the configuration shown in FIG. 5B, however, the inorganic capacitor dielectric layer 330 also wraps around the first, second capacitor plate 320-1 and the second, second capacitor plate 320-2. In this arrangement, the first, second conductive contact 350-1 lands directly on the first, second capacitor plate 320-1, and the second, second conductive contact 350-2 lands directly on the second, second capacitor plate 320-2 through the organic interlayer dielectric 302 and the inorganic capacitor dielectric layer 330.

FIG. 5C is a cross-sectional view of a vertically stacked, electrode wrap-around capacitor structure 540 according to an aspect of the present disclosure. As will be recognized, a configuration of the vertically stacked, electrode wrap-around capacitor structure 540 is similar to the configuration of the series coupled, electrode wrap-around capacitor structure 520 of FIG. 5B. In the configuration shown in FIG. 5C, however, a third capacitor plate 380 is placed between the first capacitor plate 310 and the second capacitor plate 320. In addition, the inorganic capacitor dielectric layer 330 also wraps around the third capacitor plate 380 on a first sidewall 382, a surface 386, and a second sidewall 384 of the third capacitor plate 380. In this arrangement, the first conductive contact 340 lands directly on the first capacitor plate 310, and the second conductive contact 350 lands directly on the second capacitor plate 320 through the organic interlayer dielectric 302 and the inorganic capacitor dielectric layer 330. In addition, the length L2 (FIG. 3) of the second capacitor plate 320 is equal to a length (e.g., third length) of the third capacitor plate 380. In one arrangement, the second capacitor plate 320 and the third capacitor plate 380 may be self-aligned.

FIG. 5D is a cross-sectional view of a vertically stacked, electrode wrap-around capacitor structure 560 according to an aspect of the present disclosure. As will be recognized, a configuration of the vertically stacked, electrode wrap-around capacitor structure 560 is similar to the configuration of the vertically stacked, electrode wrap-around capacitor structure 540 of FIG. 5C. In the configuration shown in FIG. 5D, however, the length L2 (FIG. 3) of the second capacitor plate 320 is less that the length (e.g., third length) of the third capacitor plate 380, such that the capacitor plates are in a pyramidal arrangement. The inorganic capacitor dielectric layer 330 also wraps around the first capacitor plate 310, the second capacitor plate 320 and the third capacitor plate 380. The first conductive contact 340 lands directly on the first capacitor plate 310, and the second conductive contact 350 lands directly on the second capacitor plate 320 through the organic interlayer dielectric 302 and the inorganic capacitor dielectric layer 330.

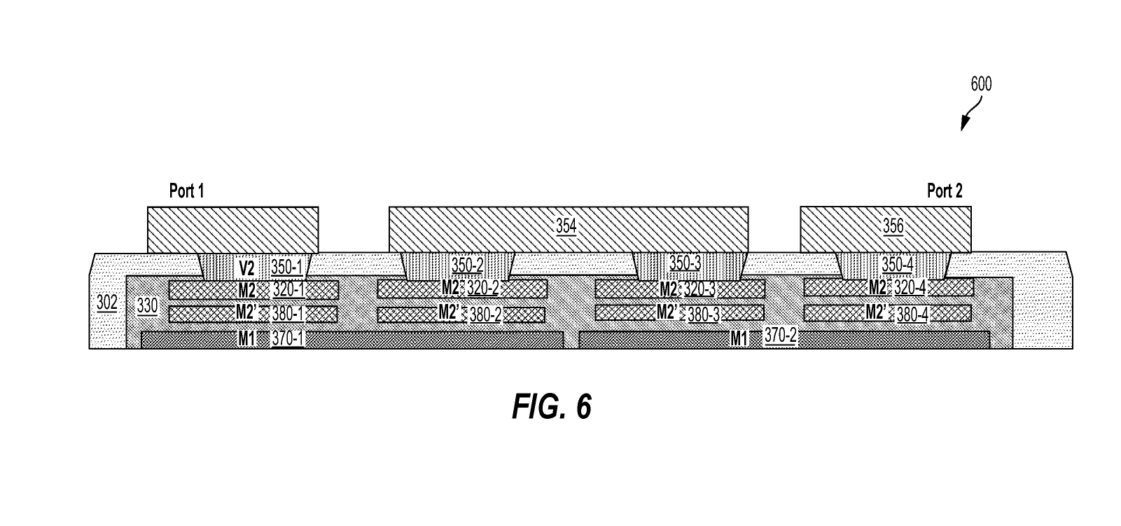

FIG. 6 is a cross-sectional view of a vertically stacked, electrode wrap-around capacitor structure 600 according to an aspect of the present disclosure. As will be recognized, a configuration of the vertically stacked, electrode wrap-around capacitor structure 600 is similar to the configuration of the vertically stacked, electrode wrap-around capacitor structure 540 of FIG. 5C. In the configuration shown in FIG. 6, however, a first, shared first capacitor plate 370-1 and a second, shared first capacitor plate 370-2 support eight parallel plate (e.g., metal-insulator-metal) capacitors. In this arrangement, a first, third capacitor plate 380-1 is between a first, second capacitor plate 320-1 and the first, shared first capacitor plate 370-1. In addition, a second, third capacitor plate 380-2 is between a second, second capacitor plate 320-2 and the first, shared first capacitor plate 370-1.

As further illustrated in FIG. 6, a third, third capacitor plate 380-3 is between a third, second capacitor plate 320-3 and the second, shared first capacitor plate 370-2. In addition, a fourth, third capacitor plate 380-4 is between a fourth, second capacitor plate 320-4 and the second, shared first capacitor plate 370-2. In this arrangement, the second portion 352 of the third conductive interconnect layer M3 is coupled to the first, second conductive contact 350-1 to provide a first port for the vertically stacked, electrode wrap-around capacitor structure 600. In addition, a third portion 354 of the third conductive interconnect layer M3 is coupled to the second, second conductive contact 350-2 and a third, second conductive contact 350-3 to electrically couple the second, second capacitor plate 320-2 and the third, second capacitor plate 320-3 in series.

In this aspect of the present disclosure, a fourth portion 356 of the third conductive interconnect layer M3 is coupled to the fourth, second conductive contact 350-4 to provide a second port for the vertically stacked, electrode wrap-around capacitor structure 600. In this arrangement, the length L2 (FIG. 3) of the second capacitor plates (e.g., 320-1, 320-2, 320-3, and 320-4) equals the length of the third capacitor plates (e.g., 380-1, 380-2, 380-3, and 380-4). The inorganic capacitor dielectric layer 330 also wraps around each of the third capacitor plates (e.g., 380-1, 380-2, 380-3, and 380-4). This arrangement of the vertically stacked, electrode wrap-around capacitor structure 600 may be designed to meet an increased RF linearity specification.

FIG. 7 illustrates a process 700 for making a wrap-around electrode capacitor structure according to aspects of the present disclosure. The process 700 begins at 710, in which a first conductive interconnect layer M1 is deposited on a substrate to form a first capacitor plate 310. At 720, an inorganic capacitor dielectric layer 330 is deposited on the first capacitor plate 310 by wrapping around a surface and sidewalls of the first capacitor plate 310. At 730, a second conductive interconnect layer M2 is deposited on the inorganic capacitor dielectric layer 330 to form a second capacitor plate 320.

At 740, an additional layer of the inorganic capacitor dielectric layer 330 may be optionally deposited and wraps around the second capacitor plate 320. At 750, a portion of the inorganic capacitor dielectric layer 330 is removed. At 760, an organic interlayer dielectric 302 is deposited and etched to expose a portion of the first capacitor plate 310 and a portion of the second capacitor plate 320. At 770, a conductive contact material is deposited on the exposed portion of the first capacitor plate 310 and the second capacitor plate to form the first conductive contact 340 and the second conductive contact 350.

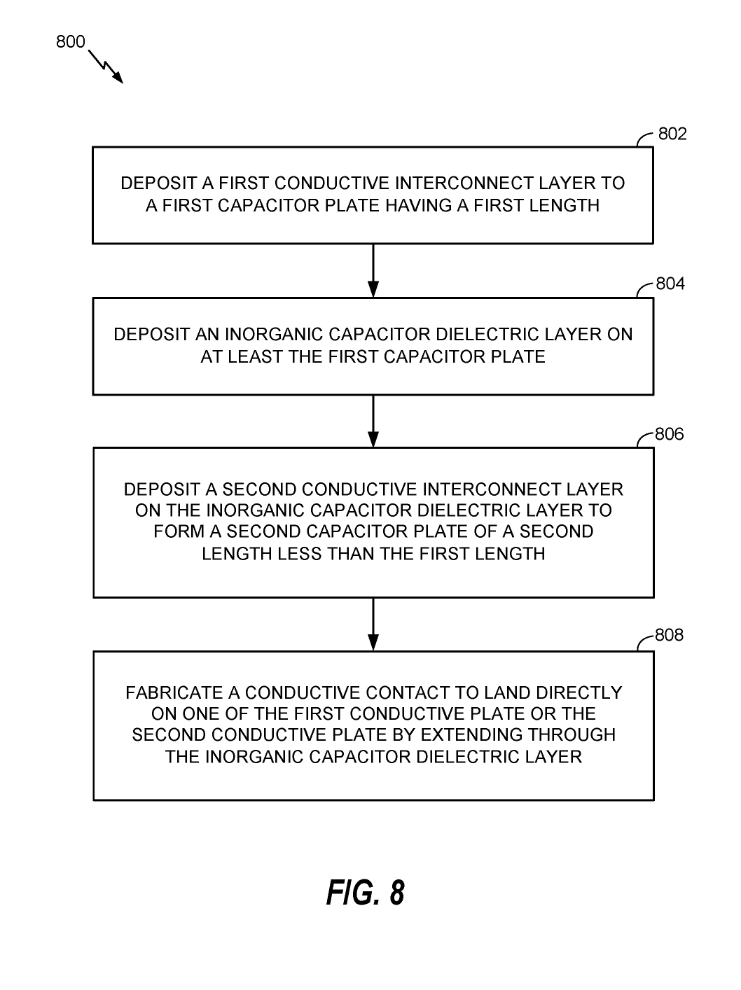

FIG. 8 is a method of constructing a structure according to aspects of the present disclosure. The method 800 begins in block 802, in which a first conductive layer is deposited to form a first capacitor plate having a first length. The first capacitor plate may be the first capacitor plate 310 having the first length L1, as shown in FIG. 3. In block 804, an inorganic capacitor dielectric layer is deposited on at least the first capacitor plate. The inorganic capacitor dielectric layer may be the inorganic capacitor dielectric layer 330 as shown in FIG. 3.

In block 806, the method 800 includes depositing a second conductive layer on the inorganic capacitor dielectric layer to form a second capacitor plate having a second length. The second capacitor plate may be the second capacitor plate 320 having the second length L2, which is less than the first length L1, as shown in FIG. 3. In block 808, a conductive contact is fabricated to land directly on the first capacitor plate or the second capacitor plate by extending through the inorganic capacitor dielectric layer and an organic interlayer dielectric supported by the inorganic capacitor dielectric layer. For example, as shown in FIG. 3, a first conductive contact 340 extends through the inorganic capacitor dielectric layer 330 and an organic interlayer dielectric 302 to land directly on the first capacitor plate 310.

For an increasing number of applications, radio frequency (RF) linearity is a significant performance consideration. Unfortunately, RF linearity is degraded when the parallel plate capacitors suffer from unintended sidewall plate connections that short the capacitor plates. These unintended sidewall plate connections short the capacitor plates, which reduces the performance of an RF device (e.g., a multiplexer/diplexer) that includes these shorted parallel plate capacitors. Aspects of the present disclosure propose electrode wrap-around capacitors for radio frequency (RF) applications. One advantage of this approach is that the fabrication process is relatively simple because the electrode wrap-around capacitor is fabricated without adding a mask layer. In addition, the electrode wrap-around capacitor provides improved RF linearity.

According to the present disclosure, an electrode wrap-around capacitor for radio frequency applications is described. The electrode wrap-around capacitor includes a second capacitor plate having a second length less than a first length of a first capacitor plate. An inorganic capacitor dielectric layer may be extended to prevent shorting between the second capacitor plate and the first capacitor plate. The electrode wrap-around capacitor may include means for electrically contacting landing directly on the first capacitor plate and/or the second capacitor plate. The means for electrically contacting may be the first conductive contact 340 and/or the second conductive contact 350, as shown in FIGS. 3-7. In another aspect, the aforementioned means may be any interconnect configured to perform the functions recited by the aforementioned means.

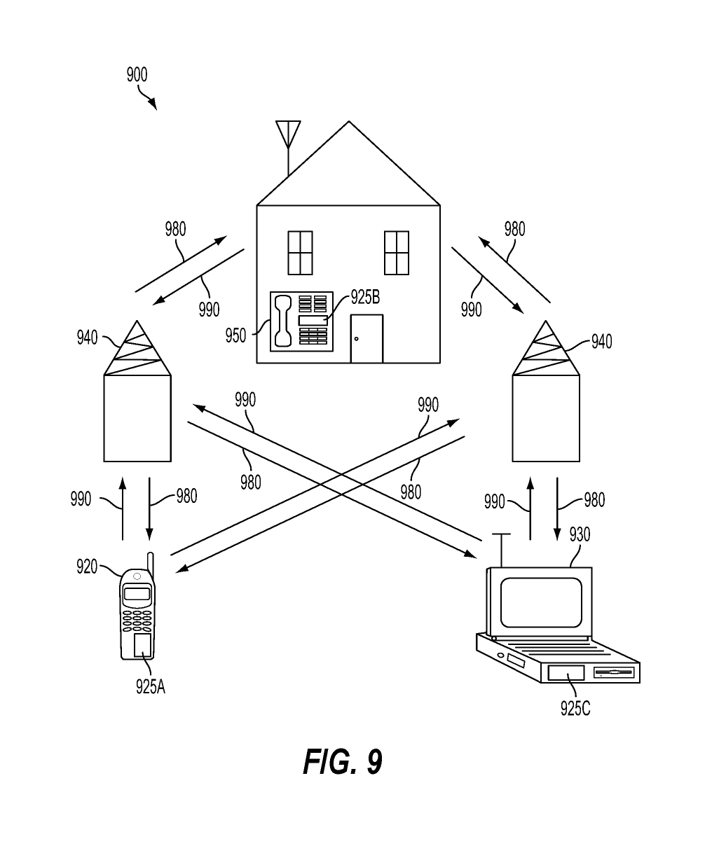

FIG. 9 is a block diagram showing an exemplary wireless communication system 900 in which an aspect of the disclosure may be advantageously employed. For purposes of illustration, FIG. 9 shows three remote units 920, 930, and 950 and base stations 940. It will be recognized that wireless communication systems may have many more remote units and base stations. Remote units 920, 930, and 950 include IC devices 925A, 925C, and 925B that include the disclosed electrode wrap-around capacitors. It will be recognized that other devices may also include the disclosed electrode wrap-around capacitors, such as the base stations, switching devices, and network equipment. FIG. 9 shows forward link signals 980 from the base stations 940 to the remote units 920, 930, and 950 and reverse link signals 990 from the remote units 920, 930, and 950 to base stations 940.

In FIG. 9, one of the remote units 920 is shown as a mobile telephone, and one of the remote units 930 is shown as a portable computer, and remote unit 950 is shown as a fixed location remote unit in a wireless local loop system. For example, the remote units may be a mobile phone, a hand-held personal communication systems (PCS) unit, a portable data unit such as a personal digital assistant (PDA), a GPS enabled device, a navigation device, a set top box, a music player, a video player, a communications device, an entertainment unit, a fixed location data unit such as a meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed electrode wrap-around capacitors.

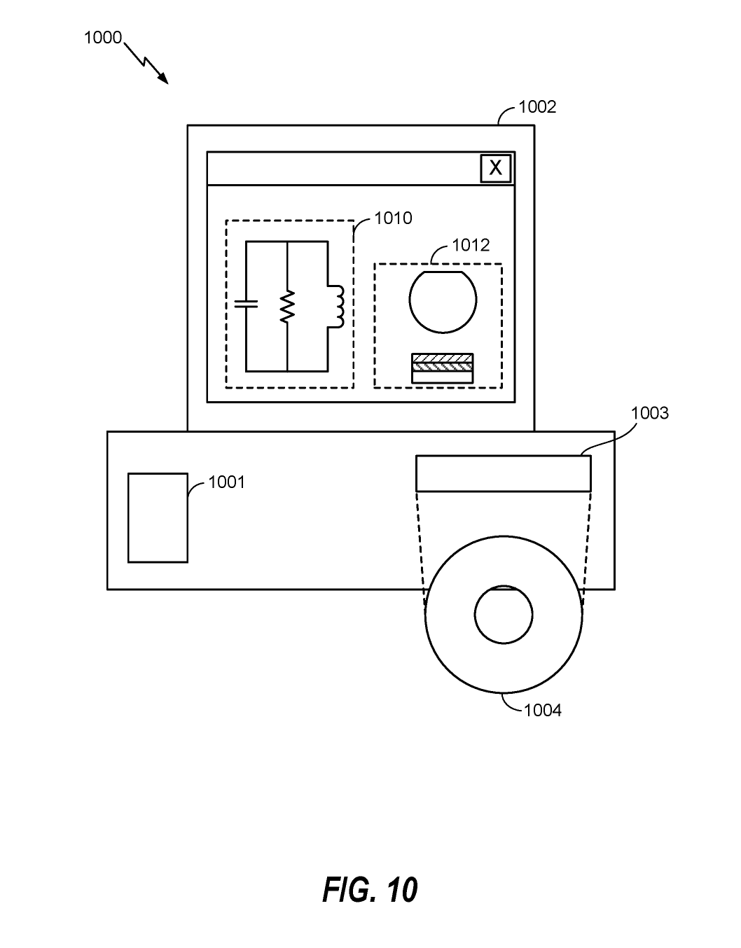

FIG. 10 is a block diagram illustrating a design workstation used for circuit, layout, and logic design of the electrode wrap-around capacitors disclosed above. A design workstation 1000 includes a hard disk 1001 containing operating system software, support files, and design software such as Cadence or OrCAD. The design workstation 1000 also includes a display 1002 to facilitate design of a circuit 1010 or the electrode wrap-around capacitors 1012. A storage medium 1004 is provided for tangibly storing the design of the circuit 1010 or the electrode wrap-around capacitors 1012. The design of the circuit 1010 or the electrode wrap-around capacitors 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the electrode wrap-around capacitors 1012 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A capacitor, comprising:
a first capacitor plate having a first length;
an inorganic capacitor dielectric layer on sidewalls and a surface of the first capacitor plate;
a second capacitor plate on the inorganic capacitor dielectric layer, the second capacitor plate having a second length less than the first length; and
a first conductive contact landing directly on the first capacitor plate by extending through the inorganic capacitor dielectric layer and an organic interlayer dielectric supported by the inorganic capacitor dielectric layer.

2. The capacitor of claim 1, in which the inorganic capacitor dielectric layer comprises a capacitor portion between the first capacitor plate and the second capacitor plate, and a protection portion on sidewalls of the first capacitor plate and the second capacitor plate.

3. The capacitor of claim 2, in which the protection portion and the capacitor portion of the inorganic capacitor dielectric layer comprise different materials.

4. The capacitor of claim 2, further comprising a second conductive contact landing directly on the second capacitor plate by extending through the protection portion of the inorganic capacitor dielectric layer.

5. The capacitor of claim 1, in which the inorganic capacitor dielectric layer is on sidewalls and on surfaces of the second capacitor plate, the capacitor further comprising a second conductive contact landing directly on the second capacitor plate by extending through the inorganic capacitor dielectric layer.

6. The capacitor of claim 1, further comprising a third capacitor plate on the inorganic capacitor dielectric layer on the first capacitor plate.

7. The capacitor of claim 6, in which the first capacitor plate is shared by the second capacitor plate and the third capacitor plate.

8. The capacitor of claim 6, in which the third capacitor plate is between the first capacitor plate and the second capacitor plate, and the inorganic capacitor dielectric layer is arranged to wrap around the third capacitor plate.

9. The capacitor of claim 8, in which the third capacitor plate has a third length equal to the second length.

10. The capacitor of claim 8, in which the third capacitor plate has a third length greater than the second length.

11. The capacitor of claim 1, integrated into a radio frequency (RF) front end module, the RF front end module incorporated into at least one of a music player, a video player, an entertainment unit, a navigation device, a communications device, a personal digital assistant (PDA), a fixed location data unit, a mobile phone, and a portable computer.

12. A capacitor, comprising:
a first capacitor plate having a first length;
a second capacitor plate supported by the first capacitor plate, the second capacitor plate having a second length less than the first length;
an inorganic capacitor dielectric layer between the first capacitor plate and the second capacitor plate, the inorganic capacitor dielectric layer on sidewalls and on surfaces of the second capacitor plate; and
a first conductive contact landing directly on the second capacitor plate by extending through the inorganic capacitor dielectric layer and an organic interlayer dielectric supported by the inorganic capacitor dielectric layer.

13. The capacitor of claim 12, further comprising a second conductive contact landing directly on the first capacitor plate by extending through the inorganic capacitor dielectric layer.

14. The capacitor of claim 12, further comprising a second conductive contact landing directly on the first capacitor plate by extending through the organic interlayer dielectric.

15. The capacitor of claim 12, integrated into a radio frequency (RF) front end module, the RF front end module incorporated into at least one of a music player, a video player, an entertainment unit, a navigation device, a communications device, a personal digital assistant (PDA), a fixed location data unit, a mobile phone, and a portable computer.

16. A method of constructing a capacitor, comprising:
depositing a first conductive interconnect layer to form a first capacitor plate having a first length;
depositing an inorganic capacitor dielectric layer on at least the first capacitor plate;
depositing a second conductive interconnect layer on the inorganic capacitor dielectric layer to form a second capacitor plate having a second length less than the first length; and
fabricating a conductive contact landing directly on at least one of the first capacitor plate or the second capacitor plate by extending through the inorganic capacitor dielectric layer and an organic interlayer dielectric supported by the inorganic capacitor dielectric layer.

17. The method of claim 16, in which depositing the inorganic capacitor dielectric layer comprises etching the inorganic capacitor dielectric layer such that a length of the inorganic capacitor dielectric layer is greater than the first length.

18. The method of claim 16, in which depositing the inorganic capacitor dielectric layer comprises depositing the inorganic capacitor dielectric layer on sidewalls and on a surface of the first capacitor plate, the conductive contact coupled to the first capacitor plate through the inorganic capacitor dielectric layer.

19. The method of claim 16, in which depositing the inorganic capacitor dielectric layer comprises depositing the inorganic capacitor dielectric layer on sidewalls and on surfaces of the second capacitor plate, the conductive contact coupled to the second capacitor plate through the inorganic capacitor dielectric layer.

20. The method of claim 16, further comprising depositing the second conductive interconnect layer on the inorganic capacitor dielectric layer on the first capacitor plate to form a third capacitor plate.

21. The method of claim 16, in which fabricating the conductive contact comprises etching through the organic interlayer dielectric supported by the inorganic capacitor dielectric layer and the inorganic capacitor dielectric layer to expose the first capacitor plate.

22. The method of claim 16, further comprising integrating the capacitor into a radio frequency (RF) front end module, the RF front end module incorporated into at least one of a music player, a video player, an entertainment unit, a navigation device, a communications device, a personal digital assistant (PDA), a fixed location data unit, a mobile phone, and a portable computer.

23. A radio frequency (RF) front end module, comprising:
a filter, comprising a capacitor having a first capacitor plate having a first length, an inorganic capacitor dielectric layer on at least the first capacitor plate, a second capacitor plate on the inorganic capacitor dielectric layer, the second capacitor plate having a second length less than the first length, and a conductive contact landing directly on at least one of the first capacitor plate or the second capacitor plate by extending through the inorganic capacitor dielectric layer and an organic interlayer dielectric supported by the inorganic capacitor dielectric layer;
a diplexer coupled to the filter; and
an antenna coupled to an output of the diplexer.

24. The RF front end module of claim 23, in which the inorganic capacitor dielectric layer is on sidewalls and on a surface of the first capacitor plate, the conductive contact coupled to the first capacitor plate through the inorganic capacitor dielectric layer.

25. The RF front end module of claim 23, in which the inorganic capacitor dielectric layer is on sidewalls and on surfaces of the second capacitor plate, the conductive contact coupled to the second capacitor plate through the inorganic capacitor dielectric layer.

26. The RF front end module of claim 23, in which the inorganic capacitor dielectric layer is on sidewalls and on surfaces of the first capacitor plate and the second capacitor plate.

27. The RF front end module of claim 23, incorporated into at least one of a music player, a video player, an entertainment unit, a navigation device, a communications device, a personal digital assistant (PDA), a fixed location data unit, a mobile phone, and a portable computer.
